(19) United States
(12) Patent Application Publication
(10) Pub. No.: US 2012/0156511 A1
(43) Pub. Date: Jun. 21, 2012

(54) COLORED CASING AND METHOD FOR FABRICATING SAME AND ELECTRONIC DEVICE HAVING SAME

(75) Inventors: CHUNG-PEI WANG, Tu-Cheng (TW); MING-YANG LIAO, Tu-Cheng (TW)

(73) Assignee: HON HAI PRECISION INDUSTRY CO., LTD., Tu-Cheng (TW)

(21) Appl. No.: 13/034,669

(22) Filed: Feb. 24, 2011

(30) Foreign Application Priority Data
Dec. 16, 2010 (TW) 99144340

(51) Int. Cl. B32B 15/04; C23C 14/35; C23C 14/06; B32B 9/00

(52) U.S. Cl. 428/457; 428/697; 204/192.15

(57) ABSTRACT

A colored casing includes a substrate having a surface to be coated, a bonding layer and a color layer. The bonding layer is consisted of chromium nitride and is formed on the surface. The color layer is formed on the bonding layer, and consisted of chromium hybrid titanium. The color layer includes a value of L* in a range from about 68.82 to about 69.82, a value of a* in a range from about −4.93 to about −3.93 and a value of b* in a range from about −12.12 to about −11.12 according to the CIE LAB system. A method for fabricating the color casing and an electronic device having the colored casing are also related.

### CROSS REFERENCE TO RELATED APPLICATION

This application is related to co-pending U.S. Patent Applications (Attorney Docket Nos. US32592, US32593, US32594, US32595, US32596, US32597, US32598, US32599, US32560, US32600, US32601, US32602, US32603, US32604, US32605, US32606 and US32607), all entitled “COLORED DEVICE CASING AND SURFACE-TREATING METHOD FOR FABRICATING SAME”. The disclosures of the above-identified applications are incorporated herein by reference.

### BACKGROUND

1. Technical Field

The present disclosure relates to device casings, and particularly, to a colored casing, a related method for fabricated the casing and an electronic device having the casing.

2. Description of Related Art

A color layer is generally formed on a surface of a casing substrate for obtaining beautiful appearance by sputtering process. However, an interface adhesive force between the color layer and the casing substrate may be not strong enough as such the color layer may be scraped from the casing substrate.

Therefore, it is desirable to provide a colored casing, a method for fabricating the casing and an electronic device which can overcome the described limitations.

### BRIEF DESCRIPTION OF THE DRAWINGS

Many aspects of the disclosure can be better understood with reference to the drawings. The components in the drawings are not necessarily drawn to scale, the emphasis instead being placed upon clearly illustrating the principles of the present disclosure. Moreover, in the drawings, like reference numerals designate corresponding parts throughout various views.

FIG. 1 is a schematic view of an electronic device with a colored casing according to an embodiment of the present disclosure.

FIG. 2 is a partial, cross-sectional view of the colored casing shown in FIG. 1, taken along line II-II.

### DETAILED DESCRIPTION

Embodiments of the disclosure will now be described in detail with reference to the accompanying drawings.

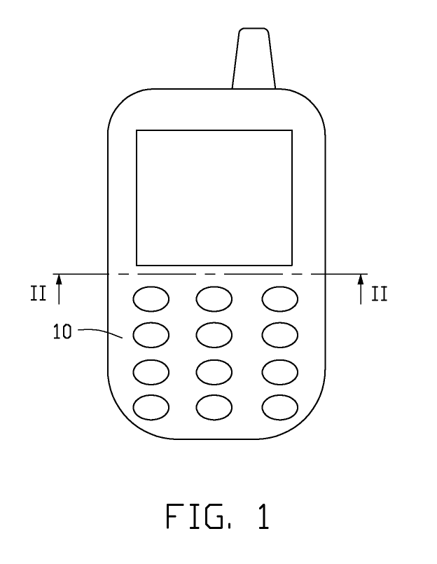

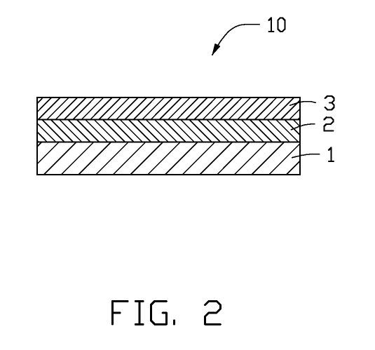

Referring to FIG. 1 and FIG. 2, an electronic device provided in accordance with an embodiment of the present disclosure is a mobile phone. The electronic device 10 includes a colored casing 10. The colored casing 10 includes a substrate 1, a bonding layer 2, made of chromium nitride and a color layer 3 are successively laminated to each other. The electronic device is not limited to the mobile phone. The colored casing 10 exhibits a Vickers hardness equaling or exceeding 500 HV.

The substrate 1 can be made of metal material such as steel, ceramic material, plastic such as PC, or glass. The substrate 1 includes a surface to be coated, i.e., the surface where the bonding layer 2 is formed. The surface can include different structure. For example, the surface includes at least one smooth region. The smooth region herein is referred to as a high-gloss or a mirror-like region. The color layer 3 is a made of a compound of titanium and chromium, wherein, a concentration ratio of the titanium and chromium is adjustable. When the concentration of titanium is far less than that of the chromium, the color layer 3 appears as a metal texture, and when the concentration of titanium is far greater than that of chromium, the color layer 3 appears as a ceramic texture. The color layer 3 has a value of L* between about 39.68 and about 41.68, a value of a* between about 4.80 and about 5.80 and a value of b* between about 6.88 and about 7.88 according to the Commission International del'Eclairage, (CIE, International Commission on Illumination) LAB system.

The colored casing 10 employs the bonding layer 2 to interconnect the colored layer 3 and the substrate 1. The interface adhesive force between the bonding layer 2 and the colored layer 3 is greater than that between the substrate 1 and the colored layer 3 directly formed on the substrate 1. Therefore, the colored casing 1, has excellent anti-abrasion properties.

The colored casing 10 can be applied to any suitable electronic device, such as a notebook or a personal digital assistant (PDA). For example, a mobile phone including the colored casing 10 shown in FIG. 1 exhibits color and metal or ceramic texture as described above, and thus provides an enhanced appearance.

Following, an exemplary method for fabricating a colored casing such as, the colored device casing 10 of FIGS. 1 and 2, will now be described in detail.

In the method, first, a substrate 1 is provided. The substrate 1 may undergo certain surface-treatments in advance as required. For instance, a pre-cleaning step may be carried out on the substrate 1, or the roughness of the substrate 1 may be enhanced to better support a subsequently formed bonding layer 2.

A bonding layer 2 is formed on a predetermined surface or region of the substrate 1 by a typical reactive magnetron sputtering process. In one embodiment, argon plasma is excited at a flow rate of about 25 standard cubic centimeters per minute (sccm) by a radio frequency (RF) generator to bombard a chromium target, and nitrogen gas is supplied at a flow rate of about 58 sccm. As a result, chromium vapor is generated and combines with the nitrogen gas, and the bonding layer 2 consisted of chromium nitride is obtained and deposits on the substrate 1.

Next, a color layer 3 is formed on the bonding layer 2 by a typical reactive magnetron sputtering process. Argon plasma is excited at a flow rate of about 200 sccm by a first power supply to bombard a titanium target, and oxygen plasma is excited at a flow rate of about 300 sccm by a second power supply to bombard a chromium target in a common sputtering chamber. The power bombarding the titanium target is about 3 kilowatts (kW), and the power bombarding the chromium target is about 25 kW. The bias voltage is in a range from 180 to 220 volts (V), the process temperature is in a range from 180° C. to 220° C., the process time is in a range from 54 to 66 minutes. The power bombarding the titanium target and chromium target may be supplied by an RF generator or a medium frequency (MF) generator. The substrate 1 revolves around an axis outside itself at 5 revolutions per minute (rpm), and rotates around its own axis at −2.7 to −3.3 rpm.

It is understood that, the concentration ratio of the titanium and the chromium in the colored layer 3 can be adjusted by changing the bombardment time at the titanium target and the chromium target. As such, the color layer 3 can exhibits metal texture or ceramic texture. Accordingly, the colored casing 10 of the present disclosure provides a desired color. The chromaticity coordinate (L*, a*, b*) of the portion of the color layer 3 is in the range from (about 68.82 to about 69.82, about −4.93 to about −3.93, about −12.12 to about −11.12) according to the CIE LAB system.

The described embodiments are intended to illustrate rather than limit the disclosure. Variations may be made to the embodiments and methods without departing from the spirit of the disclosure. Accordingly, it is appropriate that the appended claims be construed broadly and in a manner consistent with the scope of the disclosure.

1. A colored casing, comprising:
a substrate comprising a surface to be coated;
a bonding layer consisting of chromium nitride, the bonding layer formed on the surface; and
a color layer formed on the bonding layer, the color layer consisting of chromium and titanium, the color layer having a value of L* in a range from about 68.82 to about 69.82, a value of a* in a range from about −4.93 to about −3.93 and a value of b* in a range from about −12.12 to about −11.12 according to the CIE LAB system.

2. The colored device casing of claim 1, wherein the substrate is comprised of metal or ceramic material.

3. The colored device casing of claim 1, wherein a Vickers hardness of the colored casing equals or exceeds 500 HV.

4. A method for fabricating a colored casing, comprising:
a first step of providing a substrate having a surface to be coated;
a second step of forming a bonding layer on the surface using a reactive magnetron sputtering process, the bonding layer consisting of chromium nitride; and
a third step of forming a color layer to cover the bonding layer using a reactive magnetron sputtering deposition process, the color layer having a value of L* in a range from about 68.82 to about 69.82, a value of a* in a range from about −4.93 to about −3.93 and a value of b* in a range from about −12.12 to about −11.12 according to the CIE LAB system.

5. The method of claim 4, wherein the third step comprises bombarding a titanium target at a power of about 3 kW, and bombarding a chromium target at a power of about 25 kW in a common sputtering chamber.

6. The method of claim 4, wherein a bias voltage during deposition in the third step is in the range from 180 to 220V, and a deposition temperature in the third step is in the range from 180° C. to 220° C.

7. The method of claim 4, wherein the third step is performed for a time period of 54 to 66 minutes.

8. The method of claim 4, wherein in the third step, the substrate is rotated at a speed of −3.3 to −2.7 rpm.

9. An electronic device comprising a colored casing, the colored casing comprising:
a substrate comprising a surface to be coated;
a bonding layer consisting of chromium nitride, the bonding layer formed on the surface; and
a color layer formed on the bonding layer, the color layer consisting of chromium and titanium, the color layer having a value of L* in a range from about 68.82 to about 69.82, a value of a* in a range from about −4.93 to about −3.93 and a value of b* in a range from about −12.12 to about −11.12 according to the CIE LAB system.

10. The electronic device of claim 9, wherein the substrate is comprised of metal or ceramic material.

11. The electronic device of claim 9, wherein a Vickers hardness of the colored casing equals or exceeds 500 HV.
